(19) United States
(12) Patent Application Publication
(10) Pub. No.: US 2025/0040059 A1
(43) Pub. Date: Jan. 30, 2025

(54) METHOD FOR MANUFACTURING MULTILAYER PRINTED WIRING BOARD AND MULTILAYER PRINTED WIRING BOARD

(71) Applicant: PANASONIC INTELLECTUAL PROPERTY MANAGEMENT CO., LTD., Osaka (JP)

(72) Inventors: Tomoyuki KAWAHARA, Mie (JP); Kiyotaka KOMORI, Hyogo (JP); Masaya KOYAMA, Mie (JP)

(73) Assignee: PANASONIC INTELLECTUAL PROPERTY MANAGEMENT CO., LTD., Osaka (JP)

(21) Appl. No.: 18/918,956

(22) Filed: Oct. 17, 2024

Related U.S. Application Data
(62) Division of application No. 17/776,410, filed on May 12, 2022.
(60) Provisional application No. 62/934,632, filed on Nov. 13, 2019.

(51) Int. Cl. H05K 3/46; H05K 1/02; H05K 1/03

(52) U.S. Cl. CPC H05K 3/4655; H05K 1/0298; H05K 1/036; H05K 2201/0154

(57) ABSTRACT

A method includes providing a first laminate and a second laminate. The first laminate includes a first conductor layer, a first insulating layer containing polyimide, and a second conductor layer. The second laminate includes a second insulating layer containing polyimide and a third conductor layer. The method further includes: heating each of the first laminate and the second laminate under a condition including a heating temperature equal to or higher than 100° C. and a heating duration equal to or longer than half an hour; and stacking, after the heating, the first laminate and the second laminate one on top of the other with a third insulating layer interposed between the second conductor layer and the second insulating layer.

### CROSS-REFERENCE TO RELATED APPLICATIONS

This is a Divisional Application of U.S. patent application Ser. No. 17/776,410, filed May 12, 2022,which is a National Stage of International Patent Application No. PCT/JP2020/042485, filed Nov. 13, 2020, which claims priority to U.S. Provisional Patent Application No. 62/934,632filed Nov. 13, 2019. The contents of each of the above-identified applications are incorporated herein by reference in their entirety.

### TECHNICAL FIELD

The present disclosure generally relates to a method for manufacturing a multilayer printed wiring board and to a multilayer printed wiring board. More particularly, the present disclosure relates to a method for manufacturing a multilayer printed wiring board including an insulating layer containing polyimide and to such a multilayer printed wiring board.

### BACKGROUND ART

A metal-clad laminate such as flexible copper clad laminate (FCCL) has been manufactured in the art by stacking a sheet of metal foil on a film having a thermoplastic polyimide layer (see Patent Literature 1).

### Citation List

### Patent Literature

Patent Literature 1: JP 2019-210342 A

### SUMMARY OF INVENTION

The problem to be overcome by the present disclosure is to provide a method for manufacturing a multilayer printed wiring board which contributes to improving the RF characteristics of a multilayer printed wiring board including an insulating layer containing polyimide and also provide a multilayer printed wiring board including an insulating layer containing polyimide and having improved RF characteristics.

A method for manufacturing a multilayer printed wiring board according to an aspect of the present disclosure includes the step of providing a first laminate and a second laminate. The first laminate includes a first conductor layer, a first insulating layer, and a second conductor layer which are stacked one on top of another in this order. The second laminate includes a second insulating layer and a third conductor layer which are stacked one on top of the other in this order. Each of the first insulating layer and the second insulating layer contains polyimide. The method further includes: a heating step including heating each of the first laminate and the second laminate under a condition including a heating temperature equal to or higher than 100° C. and a heating duration equal to or longer than half an hour; and a stacking step including stacking, after the heating step, the first laminate and the second laminate one on top of the other with a third insulating layer interposed between the second conductor layer and the second insulating layer.

A multilayer printed wiring board according to another aspect of the present disclosure includes a first conductor layer, a first insulating layer, a second conductor layer, a third insulating layer, a second insulating layer, and a third conductor layer, which are stacked one on top of another in this order. The first insulating layer and the second insulating layer each contain polyimide. A weight variation measured by dry weight measurement method with a total volume of the first insulating layer, the second insulating layer, and the third insulating layer defined as a reference is equal to or less than 3000 μg/cm³.

### BRIEF DESCRIPTION OF DRAWINGS

FIG. 1 is a schematic cross-sectional view illustrating a first laminate, a second laminate, and a resin sheet according to an embodiment of the present disclosure;

FIG. 2 is a schematic cross-sectional view illustrating an exemplary multilayer printed wiring board according to an embodiment of the present disclosure; and

FIG. 3 is a schematic cross-sectional view illustrating another exemplary multilayer printed wiring board according to an embodiment of the present disclosure.

### Description of Embodiments

1. Overview

First, it will be described generally how the present inventors conceived the concept of the present disclosure. The present inventors carried out extensive research and development on the RF characteristics of a printed wiring board, including an insulating layer containing polyimide, to discover that the transmission loss of the printed wiring board sometimes could not be reduced as much as expected. Thus, the present inventors carried out extensive research and development on the cause of an increase in transmission loss and how to cope with such an increase in transmission loss to conceive the concept of the present disclosure.

An embodiment of the present disclosure will be described. Note that the embodiment to be described below is only an exemplary one of various embodiments of the present disclosure and should not be construed as limiting. Rather, the exemplary embodiment may be readily modified in various manners depending on a design choice or any other factor without departing from the scope of the present disclosure.

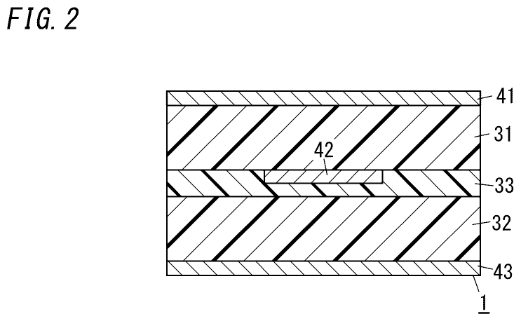

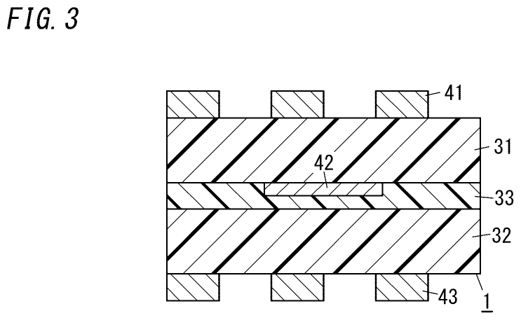

FIGS. 2 and 3 each illustrate an exemplary configuration for a multilayer printed wiring board 1 according to this embodiment. The multilayer printed wiring board 1 includes a first conductor layer 41, a first insulating layer 31, a second conductor layer 42, a third insulating layer 33, a second insulating layer 32, and a third conductor layer 43, which are stacked one on top of another in this order. The first insulating layer 31 and the second insulating layer 32 each contain polyimide.

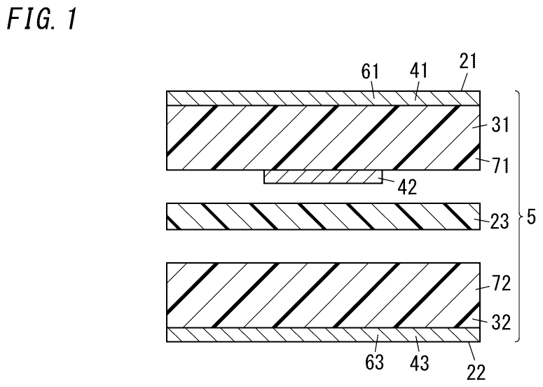

A method for manufacturing a multilayer printed wiring board 1 according to the present disclosure includes the step of providing a first laminate 21 and a second laminate 22 (see FIG. 1). The first laminate 21 includes the first conductor layer 41, the first insulating layer 31, and the second conductor layer 42, which are stacked one on top of another in this order. The second laminate 22 includes the second insulating layer 32 and the third conductor layer 43 which are stacked one on top of the other in this order. Each of the first insulating layer 31 and the second insulating layer 32 contains polyimide. The method further includes: a heating step including heating each of the first laminate 21 and the second laminate 22 under a condition including a heating temperature equal to or higher than 100° C. and a heating duration equal to or longer than half an hour; and a stacking step including stacking, after the heating step, the first laminate 21 and the second laminate 22 one on top of the other with a third insulating layer 33 interposed between the second conductor layer 42 and the second insulating layer 32.

This embodiment enables providing a multilayer printed wiring board 1 which includes the first insulating layer 31 and the second insulating layer 32 as insulating layers each containing polyimide and of which the transmission loss (i.e., the absolute value of the transmission loss) has been reduced. The reason is presumably as follows. If an insulating layer containing polyimide contains water, then the relative dielectric constant and the dielectric loss tangent of the insulating layer will increase, which causes transmission loss when an electrical signal is transmitted through the multilayer printed wiring board 1 including an insulating layer containing polyimide. In contrast, according to this embodiment, the multilayer printed wiring board 1 is manufactured through the heating step described above, and therefore, the respective water contents of the first insulating layer 31 and the second insulating layer 32, each containing polyimide, may be reduced by drying the first insulating layer 31 and the second insulating layer 32. This should reduce the respective relative dielectric constants and dielectric loss tangents of the first insulating layer 31 and the second insulating layer 32, thus lowering the transmission loss of the multilayer printed wiring board 1.

In addition, this embodiment also reduces the chances of causing an increase with time in transmission loss of the multilayer printed wiring board 1. This is presumably because manufacturing the multilayer printed wiring board 1 by the method according to this embodiment would make it easier to keep the respective water contents of the first insulating layer 31 and the second insulating layer 32 sufficiently low.

Next, a method for manufacturing the multilayer printed wiring board 1 according to the present disclosure will be described in further detail.

2. First laminate and second laminate

As described above, the first laminate 21 and the second laminate 22 are provided as materials for the multilayer printed wiring board 1.

The first laminate 21 includes the first conductor layer 41, the first insulating layer 31, and the second conductor layer 42, which are stacked one on top of another in this order.

The first conductor layer 41 may be, for example, a sheet of metal foil (first sheet of metal foil 61). The first sheet of metal foil 61 may be a sheet of copper foil, for example. The first conductor layer 41 preferably has a thickness equal to or greater than 2 μm. This reduces the chances of doing damage to the first conductor layer 41 while the first laminate 21 is being formed. The thickness is more preferably equal to or greater than 5 μm and even more preferably equal to or greater than 10 μm. The first conductor layer 41 preferably has a thickness equal to or less than 40 μm. This makes it easier to increase the flexibility of the first laminate 21. This thickness is more preferably equal to or less than 30 μm and even more preferably equal to or less than 25 μm.

The first insulating layer 31 contains polyimide as described above. The polyimide preferably has a glass transition temperature. The first insulating layer 31 may be, for example, a polyimide film (first polyimide film 71) formed by molding polyimide into a sheet shape.

Polyimide is synthesized, for example, by synthesizing a polyamic acid from an aromatic carboxylic acid dianhydride and an aromatic diamine, and imidizing the polyamic acid.

The aromatic carboxylic acid dianhydride may contain, for example, at least one selected from the group consisting of: pyromellitic dianhydride; 2,3,6,7-naphthalenetetracarboxylic dianhydride; 3,3′, 4,4′-biphenyltetracarboxylic dianhydride; 1,2,5,6-naphthalenetetracarboxylic dianhydride; 2,2′, 3,3′-biphenyltetracarboxylic dianhydride; 3,3′, 4,4′-benzophenone tetracarboxylic dianhydride; 2,2-bis (3,4-dicarboxyphenyl) propane dianhydride; 3,4,9,10-perylenetetracarboxylic dianhydride; bis (3,4-dicarboxyphenyl) propane dianhydride; 1,1-bis (2,3-dicarboxyphenyl) ethane dianhydride; 1,1-bis (3,4-dicarboxyphenyl) ethane dianhydride; bis (2,3-dicarboxyphenyl) methane dianhydride; bis (3,4-dicarboxyphenyl) ethane dianhydride; oxydiphthalic dianhydride; bis (3,4-dicarboxyphenyl) sulfonate dianhydride; p-phenylenc bis (trimellitic monoesteric anhydride); ethylene bis (trimellitic monoesteric anhydride); bisphenol A bis (trimellitic monoesteric anhydride); and derivatives thereof.

The aromatic diamine may contain, for example, at least one selected from the group consisting of: 2,2-bis [4-(4-aminophenoxy) phenyl] propane; 4,4′-diaminodiphenyl ether; 3,4′-diaminodiphenyl ether; 1,3-bis (4-aminophenoxy) benzene; 1,4-bis (4-aminophenoxy) benzene; p-phenylenediamine; 4,4′-diaminodiphenylpropane; 4,4′-diaminodiphenylmethane; benzidine; 3,3′-dichlorobenzidine; 4, 4′-diaminodiphenylsulfide; 3,3′-diaminodiphenylsulfone; 4,4′-diaminodiphenylsulfone; 4,4′-diaminodiphenyl cther; 3,3′-diaminodiphenyl ether; 3,4′-diaminodiphenyl ether;, 1, 5-diaminonaphthalene; 4,4′-diaminodiphenyldiethylsilane; 4,4′-diaminodiphenylsilane; 4,4′-diaminodiphenylethylphosphine oxide; 4,4′-diaminodiphenyl-N-methylamine; 4, 4′-diaminodiphenyl-N-phenylamine; 1,4-diaminobenzene (p-phenylenediamine); 1,3-diaminobenzene; 1,2-diaminobenzene; 2,2-bis [4-(4-aminophenoxy) phenyl] propane; 2,2′-bis (trifluoromethyl) benzidine; bis (4-aminophenyl) terephthalate; and derivatives thereof.

The polymerization method, polymerization catalyst, reaction temperature, and reaction time for obtaining polyamic acid from the aromatic carboxylic acid dianhydride and the aromatic diamine are not limited to any particular ones. The curing agent and curing condition for imidizing the polyamic acid are not limited to any particular ones, either.

The first insulating layer 31 may have a thickness equal to or greater than 25 μm and equal to or less than 500 μm, for example. Setting the thickness at 25 μm or more makes it easier to reduce the transmission loss of the multilayer printed wiring board 1. Setting the thickness at 500 μm or less increases the chances of the multilayer printed wiring board 1 having sufficient flexibility. This thickness is more preferably equal to or greater than 50 μm and even more preferably equal to or greater than 75 μm. Also, this thickness is more preferably equal to or less than 300 μm and even more preferably equal to or less than 200 μm.

The second conductor layer 42 may be, for example, conductor wiring. The conductor

wiring may be made of a metal such as copper. The second conductor layer 42 preferably has a thickness equal to or greater than 2 μm. This reduces the chances of doing damage to the second conductor layer 42 while the first laminate 21 is being formed. This thickness is more preferably equal to or greater than 5 μm and even more preferably equal to or greater than 10 μm. The second conductor layer 42 preferably has a thickness equal to or less than 40 μm. This increases the chances of the first laminate 21 having increased flexibility. This thickness is more preferably equal to or less than 30 μm and even more preferably equal to or less than 25 μm.

An exemplary method for forming the first laminate 21 will be described.

For example, a laminate is formed by stacking a sheet of metal foil (first sheet of metal foil 61), a polyimide film (first polyimide film 71), and another sheet of metal foil (second sheet of metal foil) one on top of another in this order. Then, this laminate is hot-pressed, thereby integrating the first sheet of metal foil 61, the first polyimide film 71, and the second sheet of metal foil together. Examples of the method for hot-pressing the laminate include a method using double belt pressing.

If the laminate is hot-pressed by double belt pressing, then the heating temperature is equal to or higher than 300° C. and equal to or lower than 400° C., for example, the pressing pressure is equal to or greater than 3 MPa and equal to or less than 5 MPa, for example, and the heating duration is equal to or longer than 1 minute and equal to or shorter than 5 minutes, for example.

Next, conductor wiring is formed by patterning, as needed, the second sheet of metal foil by photolithographic process, for example. This turns the first sheet of metal foil 61, the first polyimide film 71, and the second sheet of metal foil into a first conductor layer 41, a first insulating layer 31, and second conductor layer 42, respectively.

Meanwhile, the second laminate 22 includes a second insulating layer 32 and a third conductor layer 43, which are stacked one on top of the other in this order.

The third conductor layer 43 may be, for example, a sheet of metal foil (third sheet of metal foil 63). The third sheet of metal foil 63 may be, for example, a sheet of copper foil. The third conductor layer 43 preferably has a thickness equal to or greater than 2 μm. This reduces the chances of doing damage to the third conductor layer 43 while the second laminate 22 is being formed. This thickness is more preferably equal to or greater than 5 μm and even more preferably equal to or greater than 10 μm. The thickness is preferably equal to or less than 40 μm. This increases the chances of the second laminate 22 having increased flexibility. This thickness is more preferably equal to or less than 30 μm and even more preferably equal to or less than 25 μm.

The second insulating layer 32 contains polyimide as described above. The polyimide preferably has a glass transition temperature. The second insulating layer 32 may be, for example, a polyimide film (second polyimide film 72) formed by molding polyimide into a sheet shape. The polyimide may be the same as the polyimide of the first insulating layer 31.

The second insulating layer 32 may have a thickness equal to or greater than 25 μm and equal to or less than 500 μm, for example. Setting the thickness at 25 μm or more makes it easier to reduce the transmission loss of the multilayer printed wiring board 1. Setting the thickness at 500 μm or less increases the chances of the multilayer printed wiring board 1 having sufficient flexibility. This thickness is more preferably equal to or greater than 50 μm and even more preferably equal to or greater than 75 μm. Also, this thickness is more preferably equal to or less than 300 μm and even more preferably equal to or less than 200 μm.

An exemplary method for forming the second laminate 22 will be described.

For example, a laminate is formed by stacking a sheet of metal foil (third sheet of metal foil 63) and a polyimide film (second polyimide film 72) one on top of the other in this order. If necessary, an appropriate plastic film may be stacked as a mold release film on the other surface, opposite from the third sheet of metal foil 63, of the second polyimide film 72. Then, this laminate is hot-pressed, thereby integrating the third sheet of metal foil 63 and the second polyimide film 72 together. Examples of the method for hot-pressing the laminate include a method using double belt pressing.

If the laminate is hot-pressed by double belt pressing, then the heating temperature is equal to or higher than 300° C. and equal to or lower than 400° C., for example, the pressing pressure is equal to or greater than 3 MPa and equal to or less than 5 MPa, for example, and the heating duration is equal to or longer than 1 minute and equal to or shorter than 5 minutes, for example.

Subsequently, if necessary, the mold release film is peeled off the second polyimide film 72. This turns the third sheet of metal foil 63 and the second polyimide film 72 into a third conductor layer 43 and a second insulating layer 32, respectively.

3. Heating step

The first laminate 21 and the second laminate 22, which are materials for the multilayer printed wiring board 1, are each heated to a heating temperature equal to or higher than 100° C. and for a heating duration equal to or longer than half an hour, as described above. This may reduce the water content in the first laminate 21 (in particular, in the first insulating layer 31 thereof) and may also reduce the water content in the second laminate 22 (in particular, in the second insulating layer 32 thereof). The heating temperature and the heating duration are preferably set such that a thermal history Th (° C.·h), calculated by the following equation (A) using the value Tp (° C.) of the heating temperature and the value Tm (h) of the heating duration, becomes equal to or greater than 150 (° C.·h):

$$Tp \times Tm = Th \qquad ( A )$$

That is to say, if the heating temperature is 100° C., the heating duration is preferably set a value equal to or longer than 1.5 hours. If the heating duration is one hour, the heating temperature is preferably set a value equal to or higher than 150° C.

The heating temperature is preferably equal to or higher than 100° C., more preferably equal to or higher than 115° C., and even more preferably equal to or higher than 130° C. Also, the heating temperature is preferably equal to or lower than 200° C., more preferably equal to or lower than 180° C., even more preferably equal to or lower than 150° C., and particularly preferably equal to or lower than 135° C.

The heating duration is preferably equal to or longer than half an hour, more preferably equal to or longer than one hour, and even more preferably equal to or longer than two hours. Also, the heating duration is preferably equal to or shorter than ten hours, more preferably equal to or shorter than five hours, and even more preferably equal to or shorter than three hours.

The heating step may be conducted under an appropriate atmosphere such as the air atmosphere or a nitrogen atmosphere.

This heating step may be performed by heating the first laminate 21 and the second laminate 22 using an appropriate drier, for example.

4. Standby step

A method for manufacturing a multilayer printed wiring board 1 according to this embodiment preferably includes a standby step. The standby step includes placing, in an interval between the end of the heating step and the beginning of the stacking step, the first laminate 21 and the second laminate 22 in an atmosphere having a temperature equal to or higher than 18° C. and equal to or lower than 28° C. and a relative humidity equal to or greater than 45% RH and equal to or less than 65% RH for at most one hour. That is to say, the interval from the end of the heating step to the beginning of the stacking step is preferably equal to or shorter than one hour. In addition, in the interval from the end of the heating step to the beginning of the stacking step, the first laminate 21 and the second laminate 22 are preferably placed in an atmosphere having a temperature equal to or higher than 18° C. and equal to or lower than 28° C. and a relative humidity equal to or greater than 45% RH and equal to or less than 65% RH. This makes it easier to reduce the transmission loss of the multilayer printed wiring board 1. This is presumably because the first laminate 21 and the second laminate 22 are less likely to absorb water in the interval from the end of the heating step to the beginning of the stacking step.

The first laminate 21 and the second laminate 22 may be placed in the above-described atmosphere by, for example, loading the first laminate 21 and the second laminate 22 that have just gone through the heating step into a thermo-hygrostat, of which the internal space is adjusted to the above-described atmosphere.

The atmosphere in which the first laminate 21 and the second laminate 22 are placed in the standby step does not have to be the atmosphere described above. Alternatively, the first laminate 21 and the second laminate 22 may also be placed in any other appropriate atmosphere that causes the first insulating layer 31 and the second insulating layer 32 to absorb water less easily. Optionally, the method for manufacturing the multilayer printed wiring board 1 according to this embodiment may include no standby step and the stacking step may be started immediately when the heating step is finished.

5. Stacking step

The stacking step includes stacking, after the heating step, the first laminate 21 and the second laminate 22 one on top of the other with the third insulating layer 33 interposed between the second conductor layer 42 and the second insulating layer 32 as described above. That is to say, the first laminate 21, the third insulating layer 33, and the second laminate 22 are stacked one on top of another such that the second conductor layer 42 and the third insulating layer 33 are stacked one on top of the other and the third insulating layer 33 and the second insulating layer 32 are stacked one on top of the other. In this manner, the multilayer printed wiring board 1 is obtained.

The third insulating layer 33 contains, for example, a cured product of a thermosetting resin composition. In this case, the third insulating layer 33 is formed out of a resin sheet 23 containing either a dried product or semi-cured product of the thermosetting resin composition.

The thermosetting resin composition contains a thermosetting resin. The thermosetting resin composition preferably contains a polyolefin-based elastomer and a thermosetting resin. This makes it easier to increase the flexibility of the third insulating layer 33, thus making the multilayer printed wiring board 1 easily flexible. The proportion of the polyolefin-based elastomer to the entire thermosetting resin composition is preferably equal to or greater than 50% by mass and equal to or less than 95% by mass. This makes it even easier to increase the flexibility of the third insulating layer 33.

The polystyrene-based elastomer preferably contains at least one selected from the group consisting of: polystyrene-poly (ethylene/propylene) block-polystyrene copolymers; polystyrene-poly (ethylene-ethylene/propylene) block-polystyrene copolymers; polystyrene-poly (ethylene/butylene) block-polystyrene copolymers; polystyrene-polyisoprene block copolymers; hydrogenated polystyrene-polyisoprene-polybutadiene block copolymers; polystyrene-poly (butadiene/butylene) block-polystyrene copolymers; ethylene-glycidyl methacrylate copolymers; ethylene-glycidyl methacrylate-acrylate methyl copolymers; and ethylene-glycidyl methacrylate-vinyl acetate copolymers.

In this case, the thermosetting resin preferably contains at least one selected from the group consisting of epoxy resins, phenolic resins, bismaleimide resins, cyanate resins, melamine resins, imide resins and polyphenylene ether oligomers having vinyl groups at both ends thereof.

If the thermosetting resin contains an epoxy resin, the epoxy resin contains at least one resin selected from the group consisting of, for example, polyfunctional epoxy resins, bisphenol epoxy resins, novolac epoxy resins, and biphenyl epoxy resins.

The thermosetting resin composition may further contain at least one of a curing agent or a curing accelerator. The curing agent contains, for example, at least one of a phenolic curing agent or a dicyandiamide curing agent. The curing accelerator contains, for example, at least one selected from the group consisting of imidazoles, phenolic compounds, amines, and organic phosphines.

The thermosetting resin composition may further contain a filler. The filler contains, for example, at least one selected from the group consisting of silica, aluminum hydroxide, magnesium hydroxide, calcium carbonate, talc, and alumina.

The resin sheet 23 may be formed by molding the thermosetting resin composition into a sheet shape, for example, and then heating the thermosetting resin composition under an appropriate condition.

In the stacking step, first, the first laminate 21, the resin sheet 23, and the second laminate 22 are stacked, for example, such that the second conductor layer 42 and the resin sheet 23 are stacked one on top of the other and the resin sheet 23 and the second insulating layer 32 are stacked one on top of the other, thereby forming a multilayer stack 5 (see FIG. 1).

This multilayer stack 5 is hot-pressed by an appropriate method. Examples of methods for hot-pressing the multilayer stack 5 include a method that uses vacuum pressing, a heat roll laminating method that uses at least one pair of metallic rolls, and a method that uses double belt pressing.

Hot-pressing the multilayer stack 5 causes the resin sheet 23 to be softened or melted and thereby caused to flow. Subsequently, the thermosetting reaction of the resin sheet 23 is allowed to advance. In this manner, the third insulating layer 33 is formed out of the resin sheet 23 and the first laminate 21 and the second laminate 22 are bonded together via the third insulating layer 33. The multilayer printed wiring board 1 is formed in this manner (see FIG. 2).

The third insulating layer 33 preferably has a relative dielectric constant equal to or less than 2.9 and a dielectric loss tangent equal to or less than 0.003. This makes it even easier to reduce the transmission loss of the multilayer printed wiring board 1. The third insulating layer 33 is allowed to have a relative dielectric constant and a dielectric loss tangent with such values by appropriately setting the composition of the thermosetting resin composition to make the third insulating layer 33.

Optionally, the thickness of the first conductor layer 41 may be increased to a value greater than the thickness of the first sheet of metal foil 61 by subjecting the first conductor layer 41 to plating after the stacking step. Also, the thickness of the third conductor layer 43 may be increased to a value greater than the thickness of the third sheet of metal foil 63 by subjecting the third conductor layer 43 to plating.

The first conductor layer 41 may be turned into conductor wiring by patterning the first conductor layer 41 by an appropriate method such as a subtractive process after the stacking step. Likewise, the third conductor layer 43 may also be turned into conductor wiring by patterning the third conductor layer 43 by an appropriate method such as a subtractive process (see FIG. 3).

Furthermore, a via (plated through hole) may also be formed by providing a through hole through the multilayer printed wiring board 1 by an appropriate method such as laser machining or drilling and forming a conductor on the inner surface of the through hole by plating, for example.

6. Multilayer printed wiring board

The multilayer printed wiring board 1 according to this embodiment includes the first conductor layer 41, the first insulating layer 31, the second conductor layer 42, the third insulating layer 33, the second insulating layer 32, and the third conductor layer 43, which are stacked one on top of another in this order, as described above. The first insulating layer 31 and the second insulating layer 32 each contain polyimide. This multilayer printed wiring board 1 may be manufactured by, for example, the above-described method.

A weight variation measured by dry weight measurement method with a total volume of the first insulating layer 31, the second insulating layer 32, and the third insulating layer 33 defined as a reference is preferably equal to or less than 3000 μg/cm³. This makes it easier to reduce the transmission loss of the multilayer printed wiring board 1 particularly significantly. Such a low weight variation may be achieved by manufacturing the multilayer printed wiring board 1 by the above-described method, for example. The weight variation is more preferably equal to or less than 2000 μg/cm³ and even more preferably equal to or less than 500 μg/cm³. The weight variation is ideally 0 μg/cm³. A method for measuring the weight variation by the dry weight measurement method will be described in detail later with respect to specific examples.

The ratio of the total thickness of the first insulating layer 31 and the second insulating layer 32 to the total thickness of the first insulating layer 31, the second insulating layer 32, and the third insulating layer 33 is preferably equal to or greater than 67%. This makes it easier to reduce the transmission loss of the multilayer printed wiring board 1 particularly significantly. This ratio is more preferably equal to or greater than 70% and even more preferably equal to or greater than 80%. Also, this ratio is equal to or less than 98%, for example, preferably equal to or less than 95%, and even more preferably equal to or less than 85%.

In this embodiment, if an insulating layer thickness X, which is the sum of respective thicknesses of the first insulating layer 31, the second insulating layer 32, and the third insulating layer 33, is either equal to or greater than 75 μm and equal to or less than 125 μm or equal to or greater than 75 μm and less than 125 μm, then the transmission loss Y of the multilayer printed wiring board 1 may meet the following inequality (1):

$$0 > Y \geq 0.6175 X - 126.26 \qquad ( 1 )$$

and may be equal to or greater than −80.

Also, if the insulating layer thickness X is either equal to or greater than 125 μm and equal to or less than 200 μm or equal to or greater than 125 μm and less than 200 μm, then the transmission loss Y of the multilayer printed wiring board may meet the following inequality (2):

$$0 > Y \geq 0.1532 X - 68.221 \qquad ( 2 )$$

and may be equal to or greater than −49.

Furthermore, if the insulating layer thickness X is either equal to or greater than 200 um and equal to or less than 325 μm or equal to or greater than 200 μm and less than 325 μm, then the transmission loss Y of the multilayer printed wiring board may meet the following inequality (3):

$$0 > Y \geq 0.1028 X - 58.135 \qquad ( 3 )$$

and may be equal to or greater than −38.

Furthermore, if the insulating layer thickness X is equal to or greater than 325 μm and equal to or less than 1025 μm, then the transmission loss Y of the multilayer printed wiring board may meet the following inequality (4):

$$0 > Y \geq 0.0113 X - 28.397 \qquad ( 4 )$$

and may be equal to or greater than −25. Note that the unit of the transmission loss Y is dB/m.

In this embodiment, the first insulating layer 31 and the second insulating layer 32 each contain polyimide and the weight variation measured by dry weight measurement method is equal to or less than 3000 μg/cm³, thus achieving a transmission loss Y falling within any of these ranges.

### EXAMPLES

Next, specific examples of the exemplary embodiment will be described. Note that the specific examples to be described below are only examples of the exemplary embodiment and should not be construed as limiting.

1. Manufacturing first laminate

Polyimide films having thicknesses of 25 μm, 38 μm, 50 μm, 75 μm, 137.5 μm, and 500um (product name UPILEX VT manufactured by Ube Industries, Ltd.; having a relative weight of 1.2) and a sheet of copper foil having a thickness of 12 μm (product number GHY5-93F-HA-V2manufactured by JX Nippon Mining & Metals Corporation) were provided.

A polyimide film, of which the thickness corresponded to the thickness of the first insulating layer (see Tables 3 and 4) in each of specific examples, was used. A multilayer stack, in which a sheet of copper foil, the polyimide film, and another sheet of copper foil were stacked one on top of another in this order such that a matte surface of each sheet of copper foil was laid on top of the polyimide film, was hot-pressed by double belt method under the condition including a heating temperature of 330° C., a pressing pressure of 4 MPa, and a heating duration of 5 minutes.

The half-finished product thus obtained was cut off so as to have planar dimensions of 250 mm×250 mm.

Subsequently, one sheet of copper foil of the half-finished product was patterned by subtractive process using a photosensitive dry film as an etch photoresist and a copper (II) chloride solution as an etchant, thereby forming conductor wiring. In this manner, the first laminate was formed.

2. Manufacturing second laminate

Polyimide films having thicknesses of 25 μm, 38 μm, 50 μm, 75 μm, 137.5 μm, and 500um (product name UPILEX VT manufactured by Ube Industries, Ltd.) and a sheet of copper foil having a thickness of 12 μm were provided.

A polyimide film, of which the thickness corresponded to the thickness of the second insulating layer (see Tables 3 and 4) in each of specific examples, was used. A multilayer stack, in which a sheet of copper foil, the polyimide film, and a mold release film (product name UPILEX S manufactured by Ube Industries, Ltd.; having a thickness of 25 μm) were stacked one on top of another in this order such that a matte surface of the sheet of copper foil was laid on top of the polyimide film, was hot-pressed by double belt method under the condition including a heating temperature of 330° C., a pressing pressure of 4 MPa, and a heating duration of 5 minutes. Subsequently, the mold release film was peeled off the polyimide film.

In this manner, the second laminate was formed. Then, the second laminate was cut off so as to have planar dimensions of 250 mm×250 mm.

3. Heating step

The first laminate and the second laminate were loaded into a drier and heated under the air atmosphere. At this time, the heating temperature and the heating duration were as described in the “Heating Step Condition” in Table 1.

4. Standby step

In first through twelfth examples, as soon as the heating step was finished, the first laminate and the second laminate were loaded into a thermo-hygrostat. The temperature and humidity in the thermo-hygrostat and the duration for which the first laminate and the second laminate were loaded in the thermo-hygrostat were as described in the “Standby Step Condition” in Tables 3 and 4.

5. Stacking step

As soon as the standby step was finished, the first laminate, a resin sheet (sheet-shaped low-transmission-loss flexible multilayer board material, product number R-BM17 available from Panasonic Corporation, having a thickness of 25 um), and the second laminate were stacked one on top of another in this order such that the conductor wiring of the first laminate was laid on top of the resin sheet and that the resin sheet was laid on top of the polyimide film of the second laminate to form a multilayer stack. Then, the multilayer stack was hot-pressed using a daylight press machine in a reduced pressure atmosphere of 50 torr (=50×(101325/760) Pa) or less under the condition including the highest heating temperature of 180° C., a pressing pressure of 2 MPa, and a heating duration of one hour. In this manner, a multilayer printed wiring board was obtained.

6. Forming conductor wiring and other members

Each of the two sheets of copper foil of the multilayer printed wiring board was plated to increase the thickness of the sheet of copper foil to 27 μm. In addition, the multilayer printed wiring board was drilled to make a through hole having a diameter of 300 μm. Furthermore, each sheet of copper foil and the through hole were patterned by subtractive process using a photosensitive dry film as an etch photoresist and a copper (II) chloride solution as an etchant, thereby forming conductor wiring with a thickness of 27 μm and also forming a via (plated through hole) with the inner surface of the through hole plated with a copper film. The respective residual copper ratios of the conductor wiring corresponding to the first conductor layer and the conductor wiring corresponding to the third conductor layer are shown in Tables 3 and 4. Subsequently, the etch photoresist was removed by polishing with a piece of sandpaper.

7. Relative dielectric constant and dielectric loss tangent of third insulating layer

Eight resin sheets (product number R-BM17), each of which was used as in the “5.Stacking step” section described above, were stacked one on top of another and hot-pressed and thereby cured in a reduced pressure atmosphere of 50 torr (=50×(101325/760) Pa) or less under the condition including the highest heating temperature of 180° C., a pressing pressure of 2 MPa, and a heating duration of one hour. In this manner, a sample was formed. The dielectric properties (including the relative dielectric constant and dielectric loss tangent) of this sample at a frequency of 10 GHz were measured by cavity resonator method using a network analyzer (product number E5071C manufactured by Keysight Technologies). As a result, the relative dielectric constant was 2.2 and the dielectric loss tangent was 0.0012.

8. Weight variation measured by dry weight measurement method

The weight of the multilayer printed wiring board was measured with a precision electronic scale.

The multilayer printed wiring board was heated to 135° C. in the air for two hours to be dried. The weight of the multilayer printed wiring board as dried was measured with a precision electronic scale.

Based on the result of this measurement, the weight variation (of which the unit is μg/cm³) was calculated by the following expression. Note that the value of the weight variation was defined by rounding off the calculated value to one decimal place.

$$( A - B ) / \{ ( C - D ) \times E \times 0.1 \} \times 1000000$$

The respective parameters in this expression are defined as follows:
A: weight (g) of the multilayer printed wiring board that had not been dried yet;
B: weight (g) of the multilayer printed wiring board that had just been dried;
C: planar area (cm²) of the multilayer printed wiring board, which was 625 cm² in this test;
D: sum of the respective planar areas (cm²) of plated through holes of the multilayer printed wiring board, which was 6.25 cm² in this test; and
E: sum of respective thicknesses (mm) of the first insulating layer, the second insulating layer, and the third insulating layer.

The parameter values in the respective examples are as shown in the following Tables 1 and 2:

TABLE 1

| | Example 1 | Example 2 | Example 3 | Example 4 | Example 5 | Example 6 | Example 7 |
|---|---|---|---|---|---|---|---|
| A | 39.7241 | 21.8152 | 17.2513 | 30.9429 | 26.3790 | 37.4710 | 102.8094 |
| B | 39.7222 | 21.8146 | 17.2510 | 30.9416 | 26.3781 | 37.4693 | 102.8031 |
| C | 625 | 625 | 625 | 625 | 625 | 625 | 625 |
| D | 6.25 | 6.25 | 6.25 | 6.25 | 6.25 | 6.25 | 6.25 |
| E | 0.325 | 0.125 | 0.075 | 0.225 | 0.175 | 0.3 | 1.025 |

TABLE 2

| | | | | | | Comparative | Comparative |
|---|---|---|---|---|---|---|---|
| | Example 8 | Example 9 | Example 10 | Example 11 | Example 12 | Example 1 | Example 2 |
| A | 19.6245 | 39.7899 | 21.8676 | 39.8024 | 21.8781 | 39.7899 | 21.8676 |
| B | 19.6241 | 39.7241 | 21.8152 | 39.7241 | 21.8152 | 39.7241 | 21.8152 |
| C | 625 | 625 | 625 | 625 | 625 | 625 | 625 |
| D | 6.25 | 6.25 | 6.25 | 6.25 | 6.25 | 6.25 | 6.25 |
| E | 0.101 | 0.325 | 0.125 | 0.075 | 0.225 | 0.325 | 0.125 |

9. Transmission loss (initial)

The transmission losses caused when an electrical signal applied at a frequency of 20 GHz was transmitted through a wire (A) under test with a length of 1000 mm and a wire (B) under test with a length of 750 mm in conductor wiring corresponding to the second conductor layer of the multilayer printed wiring board were measured using a network analyzer (product number E5071C manufactured by Keysight Technologies). The difference (A)-(B) between the transmission losses thus measured was calculated and multiplied by four to obtain a transmission loss (dB/m). Note that a wire with an impedance of 50 02 was used as each wire under test.

10. Transmission loss (after having been treated at 23° C. and 50% for 24 hours)

The multilayer printed wiring board was loaded in a thermo-hygrostat, of which the internal atmosphere was adjusted to 23° C. and 50% RH, for 24 hours and then the transmission loss was measured in the same way as in the “Transmission loss (initial)” section described above.

11. Transmission loss (after having been treated at 40° C. and 90% for 96 hours)

The multilayer printed wiring board was loaded in a thermo-hygrostat, of which the internal atmosphere was adjusted to 40° C. and 90% RH, for 96 hours and then the transmission loss was measured in the same way as in the “Transmission loss (initial)” section described above.

12. Test results

The results of these tests are summarized in the following Tables 3 and 4:

TABLE 3

| | Ex. 1 | Ex. 2 | Ex. 3 | Ex. 4 | Ex. 5 | Ex. 6 | Ex. 7 |
|---|---|---|---|---|---|---|---|
| Thickness (μm) of first | 150 | 50 | 25 | 100 | 75 | 137.5 | 500 |
| insulating layer | | | | | | | |
| Thickness (μm) of second | 150 | 50 | 25 | 100 | 75 | 137.5 | 500 |
| insulating layer | | | | | | | |
| Thickness (μm) of third | 25 | 25 | 25 | 25 | 25 | 25 | 25 |
| insulating layer | | | | | | | |
| Total thickness (μm) of | 325 | 125 | 75 | 225 | 175 | 300 | 1025 |
| insulating layers | | | | | | | |
| Ratio of combined thickness of first | 0.92 | 0.80 | 0.67 | 0.89 | 0.86 | 0.92 | 0.98 |
| and second insulating layers to total | | | | | | | |
| thickness of insulating layers | | | | | | | |
| Heating step condition | 135° C. | 135° C. | 135° C. | 135° C. | 135° C. | 135° C. | 135° C. |
| | 2 hr. | 2 hr. | 2 hr. | 2 hr. | 2 hr. | 2 hr. | 2 hr. |
| Standby step condition | 23° C. | 23° C. | 23° C. | 23° C. | 23° C. | 23° C. | 23° C. |
| | 55% RH | 55% RH | 55% RH | 55% RH | 55% RH | 55% RH | 55% RH |
| | 1 hr. | 1 hr. | 1 hr. | 1 hr. | 1 hr. | 1 hr. | 1 hr. |
| Residual copper ratios of first | 99% | 99% | 99% | 99% | 99% | 99% | 99% |
| and third conductor layers | | | | | | | |
| Weight variation (μg/cm³) | 93.2 | 80.8 | 67.3 | 89.8 | 86.6 | 92.6 | 98.5 |
| Transmission loss (initial) (dB/m) | −20.9 | −44.8 | −71 | −28.6 | −35.5 | −22.5 | −14.2 |
| Transmission loss (after being treated | −20.9 | −44.8 | −71 | −28.6 | −35.5 | −22.5 | −14.2 |
| at 23° C. and 50% for 24 hours) (dB/m) | | | | | | | |
| Transmission loss (after being treated | −20.9 | −44.8 | −71 | −28.6 | −35.5 | −22.5 | −14.2 |
| at 40° C. and 90% for 96 hours) (dB/m) | | | | | | | |

TABLE 4

| | Ex. 8 | Ex. 9 | Ex. 10 | Ex. 11 | Ex. 12 | Cmp. Ex. 1 | Cmp. Ex. 2 |
|---|---|---|---|---|---|---|---|
| Thickness (μm) of first | 38 | 150 | 50 | 150 | 50 | 150 | 50 |
| insulating layer | | | | | | | |
| Thickness (μm) of second | 38 | 150 | 50 | 150 | 50 | 150 | 50 |
| insulating layer | | | | | | | |
| Thickness (μm) of third | 25 | 25 | 25 | 25 | 25 | 25 | 25 |
| insulating layer | | | | | | | |
| Total thickness (μm) of | 100 | 325 | 125 | 325 | 125 | 325 | 125 |
| insulating layers | | | | | | | |
| Ratio of combined thickness of first | 0.76 | 0.92 | 0.80 | 0.92 | 0.80 | 0.92 | 0.80 |
| and second insulating layers to total | | | | | | | |
| thickness of insulating layers | | | | | | | |
| Heating step condition | 135° C. | 135° C. | 135° C. | 135° C. | 135° C. | — | — |
| | 2 hr. | 2 hr. | 2 hr. | 2 hr. | 2 hr. | | |
| Standby step condition | 23° C. | 23° C. | 23° C. | 23° C. | 23° C. | — | — |
| | 55% RH | 55% RH | 55% RH | 55% RH | 55% RH | | |
| | 1 hr. | 24 hr. | 24 hr. | 1 hr. | 1 hr. | | |
| Residual copper ratios of first | 99% | 99% | 99% | 40% | 40% | 99% | 99% |
| and third conductor layers | | | | | | | |
| Weight variation (μg/cm³) | 76.0 | 3273.8 | 6782.5 | 16875.4 | 4520.8 | 3273.8 | 6782.5 |
| Transmission loss (initial) (dB/m) | −58.1 | −25.2 | −49.8 | −23.0 | −47.0 | −27.0 | −51.0 |
| Transmission loss (after being treated | −58.1 | −25.2 | −49.8 | −25.2 | −49.1 | −27.0 | −51.0 |
| at 23° C. and 50% for 24 hours) (dB/m) | | | | | | | |
| Transmission loss (after being treated | −58.1 | −25.2 | −49.8 | −47.9 | −71.8 | −27.0 | −51.0 |
| at 40° C. and 90% for 96 hours) (dB/m) | | | | | | | |

These results reveal that comparing the results obtained in the first and ninth examples with the results obtained in the first comparative example in each of which the insulating layer had the same total thickness, the transmission loss value improved in the first and ninth examples, of which the manufacturing method included the heating step, compared to the first comparative example, of which the manufacturing method included no heating step. In the same way, comparing the results obtained in the second, tenth and twelfth examples with the results obtained in the second comparative example, the transmission loss value improved in the second, tenth, and twelfth examples compared to the second comparative example.

Among the first through twelfth examples, in the first to eighth examples, the weight variation was particularly low (i.e., the water content of the insulating layer containing polyimide was particularly low) and the transmission loss values were within the range defined by inequality (1), (2), (3), or (4).

In addition, comparing the results obtained in the first example with those obtained in the eleventh example, the transmission loss deteriorated less easily in the first example with the higher residual copper ratio than in the eleventh example, even when subjected to the heating and humidification treatment. In the same way, comparing the results obtained in the second example with those obtained in the twelfth example, the transmission loss deteriorated less easily in the second example with the higher residual copper ratio than in the twelfth example, even when subjected to the heating and humidification treatment. Thus, it was confirmed that the higher the residual copper ratio of the first and third conductor layers was, the less easily the transmission loss deteriorated with time. Note that the respective residual copper ratios of the first and third conductor layers are preferably equal to or greater than 40% and more preferably equal to or greater than 60%.

1. A method for manufacturing a multilayer printed wiring board, the method comprising:
providing a first laminate and a second laminate, the first laminate including a first conductor layer, a first insulating layer containing polyimide, and a second conductor layer which are stacked one on top of another in this order, the second laminate including a second insulating layer containing polyimide and a third conductor layer which are stacked one on top of the other in this order;
heating each of the first laminate and the second laminate under a condition including a heating temperature equal to or higher than 100° C. and a heating duration equal to or longer than half an hour; and
stacking, after heating, the first laminate and the second laminate one on top of the other with a third insulating layer interposed between the second conductor layer and the second insulating layer.

2. The method of claim 1, further comprising placing, in an interval from an end of the heating to a beginning of the stacking, the first laminate and the second laminate in an atmosphere having a temperature equal to or higher than 18° C. and equal to or lower than 28° C. and a relative humidity equal to or less than 65% RH for at most one hour.

3. The method of claim 1, wherein
a weight variation measured by dry weight measurement method with a total volume of the first insulating layer, the second insulating layer, and the third insulating layer defined as a reference is equal to or less than 3000 μg/cm³.

4. The method of claim 1, wherein
the first insulating layer and the second insulating layer each have a thickness equal to or greater than 25 μm and equal to or less than 500 μm.

5. The method of claim 1, wherein
a ratio of a total thickness of the first insulating layer and the second insulating layer to a total thickness of the first insulating layer, the second insulating layer, and the third insulating layer is equal to or greater than 67%.

6. The method of claim 1, wherein
an insulating layer thickness X, which is a sum of respective thicknesses of the first insulating layer, the second insulating layer, and the third insulating layer, is equal to or greater than 75 μm and equal to or less than 125 μm, and
a transmission loss Y of the multilayer printed wiring board meets the following inequality (1):
$$0 > Y \geq 0.6175 X - 126.26 \qquad ( 1 )$$
and is equal to or greater than −80.

7. The method of claim 1, wherein
an insulating layer thickness X, which is a sum of respective thicknesses of the first insulating layer, the second insulating layer, and the third insulating layer, is equal to or greater than 125 μm and equal to or less than 200 μm, and
a transmission loss Y of the multilayer printed wiring board meets the following inequality (2):
$$0 > Y \geq 0.1532 X - 68.221 \qquad ( 2 )$$
and is equal to or greater than-49.

8. The method of claim 1, wherein
an insulating layer thickness X, which is a sum of respective thicknesses of the first insulating layer, the second insulating layer, and the third insulating layer, is equal to or greater than 200 μm and equal to or less than 325 μm, and
a transmission loss Y of the multilayer printed wiring board meets the following inequality (3):
$$0 > Y \geq 0.1028 X - 58.135 \qquad ( 3 )$$
and is equal to or greater than −38.

9. The method of claim 1, wherein
an insulating layer thickness X, which is a sum of respective thicknesses of the first insulating layer, the second insulating layer, and the third insulating layer, is equal to or greater than 325 μm and equal to or less than 1025 μm, and
a transmission loss Y of the multilayer printed wiring board meets the following inequality (4):
$$0 > Y \geq 0.0113 X - 28.397 \qquad ( 4 )$$
and is equal to or greater than −25.

10. The method of claim 1, wherein
the third insulating layer has a dielectric constant equal to or less than 2.9, and
the third insulating layer has a dielectric loss tangent equal to or less than 0.003.
